(19) United States
(12) Patent Application Publication
(10) Pub. No.: US 2026/0143727 A1
(43) Pub. Date: May 21, 2026

(54) FLIP-CHIP DIODE STRUCTURE AND MANAFACTURING METHOD THEREOF

(71) Applicant: Taiwan-Asia Semiconductor Corporation, Hsinchu City (TW)

(72) Inventor: Hou-Jun Wu, Hsinchu City (TW)

(21) Appl. No.: 19/191,778

(22) Filed: Apr. 28, 2025

(30) Foreign Application Priority Data
Nov. 18, 2024 (TW) 113144227

(51) Int. Cl. H10D 8/25; H01L 23/31; H10D 8/01; H10D 64/62

(52) U.S. Cl. CPC H10D 8/25; H10D 8/022; H10D 64/62; H10W 74/134

(57) ABSTRACT

A flip-chip diode structure is provided, which comprises: a substrate, two junction regions, two metal electrodes and a dielectric layer. The substrate includes two arc recesses, respectively disposed at opposite edges of the substrate. The two junction regions are disposed within the substrate. Two metal electrodes are disposed on the same side of the substrate and each electrically connected to one of the two junction regions. The dielectric layer covers the arc recesses and the top surface of the substrate between the two metal electrodes. Each of the arc recesses is adjacent to the outer side of one of the metal electrodes, and the maximum depth of the two junction regions within the substrate is less than the depth of the arc recesses.

### CROSS-REFERENCES TO RELATED APPLICATIONS

This application claims the benefit of priority to Taiwanese Patent Application No. 113144227 filed on Nov. 18, 2024, which is hereby incorporated by reference in its entirety.

### BACKGROUND OF THE INVENTION

### Field of the Invention

The present invention relates to a flip-chip diode structure and a manufacturing method thereof, and in particular to a flip-chip diode structure and its manufacturing method designed to prevent short circuits during die bonding.

### Descriptions of the Related Art

With the maturing development of semiconductor diodes, their applications have become increasingly widespread in recent years. One packaging application involves encapsulating a chip in a flip-chip form to enhance the optical or thermal dissipation efficiency of semiconductor components. As shown in FIG. 1, a conventional flip-chip Zener diode structure 1 is depicted, comprising a substrate 10, a P-type junction region 20, an N-type junction region 30, and two metal electrodes 40 each electrically connected to one of the junction regions. The flip-chip Zener diode structure 1 is bonded to a substrate 2 via the two metal electrodes 40 and solder 50. As illustrated, the arrows indicate the current flow path in the flip-chip Zener diode structure 1 under normal bonding conditions, showing an external current flowing from one metal electrode into the internal PN junctions of the component and then exiting through the other metal electrode.

In the flip-chip Zener diode structure 1, the metal electrodes 40 and solder 50 commonly use metal materials such as gold-tin (AuSn) alloys or nickel-gold (NiAu) alloys. Due to the low melting point of tin, during die bonding, the tin flows and adheres to the sidewall of the substrate which has an opposite polarity to that of the original metal electrode. As shown in FIG. 2, unintended solder overflow formed on the component's sidewall during bonding leads to a short circuit between the P electrode and N electrode. The current path illustrated represents a possible short-circuit path that bypasses the intended route between the P-type junction region 20 and N-type junction region 30 and results in component failure. In view of this, there is an urgent need in the industry for an innovative flip-chip diode structure to prevent the aforementioned short-circuit issues caused by solder overflow during die bonding.

### SUMMARY OF THE INVENTION

The main objective of the present invention is to provide an innovative flip-chip diode structure and its manufacturing method. When performing flip-chip die bonding, even if solder overflow occurs from the electrodes, the inventive flip-chip diode structure reduces the likelihood of short circuits, prevents component failure, and improves the yield rate of the die bonding and packaging process.

To achieve the above objective, the present invention provides a flip-chip diode structure comprising a substrate, two junction regions, two metal electrodes, and a dielectric layer. The substrate includes two arc recesses respectively disposed at opposite edges of the substrate. The two junction regions are disposed within the substrate. The two metal electrodes are disposed on the same side of the substrate, each electrically connected to one of the two junction regions. The dielectric layer covers the arc recesses and the top surface of the substrate between the two metal electrodes. Each of the arc recesses is adjacent to the outer side of one of the metal electrodes, and the maximum depth of the two junction regions within the substrate is less than the depth of the arc recesses.

In one embodiment of the flip-chip diode structure of the present invention, the maximum depth of the two junction regions within the substrate is between 5-10 micrometers (μm).

In one embodiment of the flip-chip diode structure of the present invention, the depth of the two arc recesses is greater than 10 micrometers (μm).

In one embodiment of the flip-chip diode structure of the present invention, each arc recess has an arc angle between 30° and 60°, wherein the arc angle is defined as the angle between a diffusion depth line of each junction region extending to a tangent line of each arc recess.

In one embodiment of the flip-chip diode structure of the present invention, the dielectric layer is one of a silicon dioxide layer and a silicon nitride layer.

In one embodiment of the flip-chip diode structure of the present invention, the thickness of the dielectric layer is between 1-2 micrometers (μm).

In one embodiment of the flip-chip diode structure of the present invention, the dielectric layer between the two metal electrodes is substantially the same height as the two metal electrodes.

In one embodiment of the flip-chip diode structure of the present invention, each metal electrode is one of a gold-tin alloy and a nickel-gold alloy.

In one embodiment of the flip-chip diode structure of the present invention, the two junction regions include a P-type junction region and an N-type junction region.

In one embodiment of the flip-chip diode structure of the present invention, the two junction regions include two P-type junction regions.

In one embodiment of the flip-chip diode structure of the present invention, the two junction regions include two N-type junction regions.

To achieve the above objective, the present invention provides a manufacturing method for a flip-chip diode structure, comprising the following steps. First, provide two junction regions disposed within a substrate. Second, remove a portion of the substrate to form two arc recesses respectively disposed at opposite edges of the substrate. Next, provide two metal electrodes disposed on the same side of the substrate, each electrically connected to one of the two junction regions. Finally, provide a dielectric layer covering the arc recesses and the top surface of the substrate between the two metal electrodes, wherein each arc recess is adjacent to the outer side of one of the metal electrodes, and the maximum depth of the two junction regions within the substrate is less than the depth of the arc recesses.

In another embodiment of the manufacturing method of the flip-chip diode structure of the present invention, the step of removing a portion of the substrate to form two arc recesses is performed by etching a portion of the substrate.

In another embodiment of the manufacturing method of the flip-chip diode structure of the present invention, the step of providing a dielectric layer is performed by coating or deposition to form the dielectric layer.

In another embodiment of the manufacturing method of the flip-chip diode structure of the present invention, the method further includes a step of planarizing the dielectric layer between the two metal electrodes to make it substantially the same height as the two metal electrodes.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic diagram of a conventional flip-chip Zener diode structure;

FIG. 2 is a schematic diagram of a conventional flip-chip Zener diode structure showing a short circuit due to solder overflow;

FIG. 3 to FIG. 7 are schematic diagrams illustrating the manufacturing of the flip-chip diode structure of the present invention;

FIG. 8 is a schematic diagram of an embodiment of the flip-chip diode structure of the present invention bonded to a substrate; and

FIG. 9 is a schematic diagram of the process steps for manufacturing the flip-chip diode structure of the present invention.

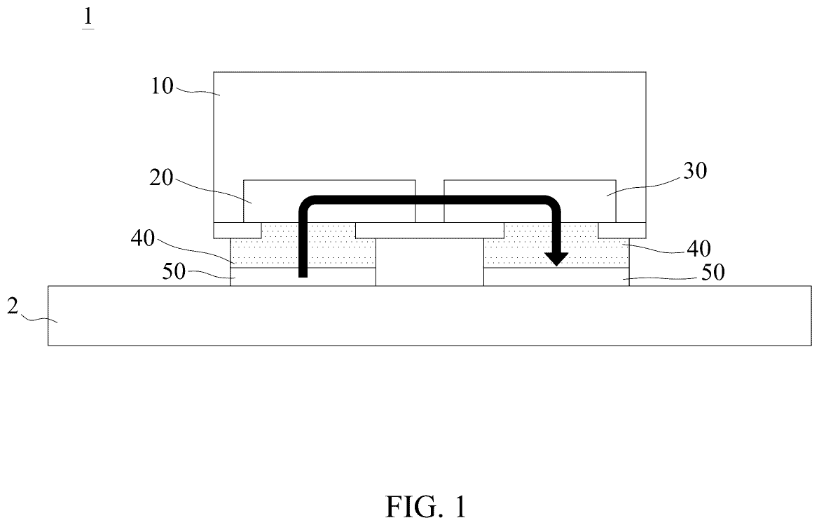

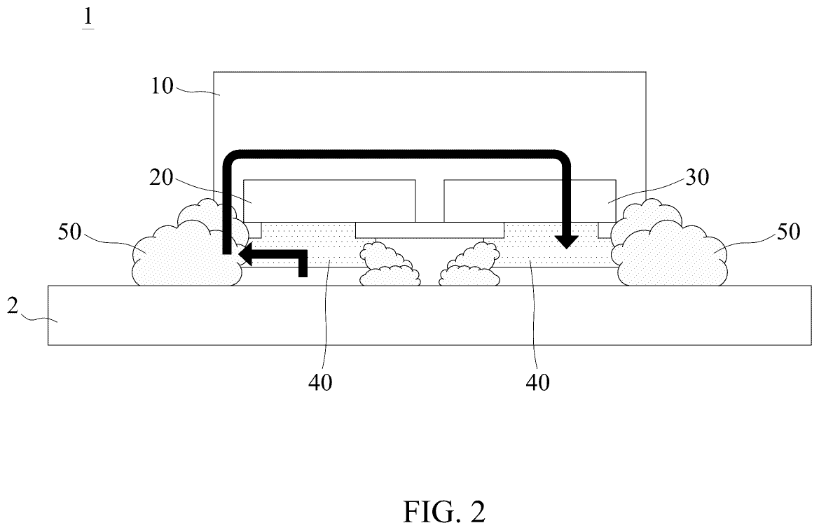

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

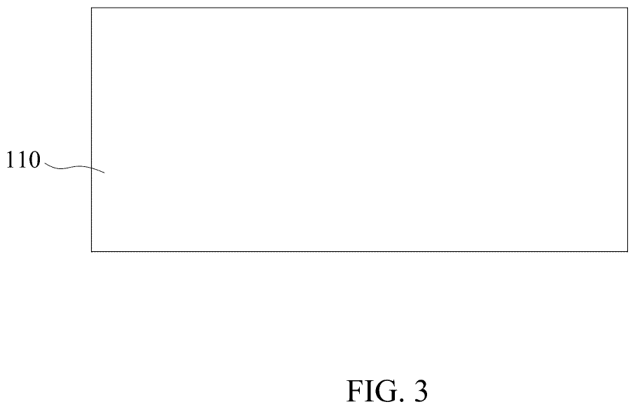

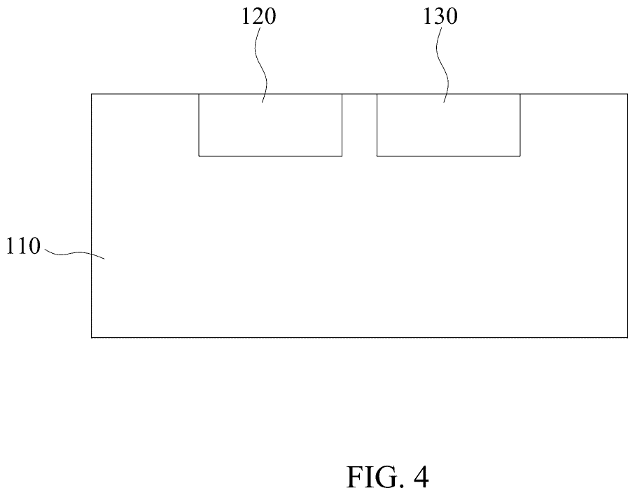

The present invention discloses a flip-chip diode structure and its manufacturing method. Referring to FIG. 3, in a specific embodiment, a substrate 110 is first provided, which may be formed epitaxially as a first conductivity-type compound semiconductor layer, such as an N-type gallium arsenide (GaAs) layer, doped with sulfur(S) or silicon (Si) as an N-type dopant at a low concentration of, for example, 10¹² to 10¹⁵/cm³, though not limited thereto. Next, referring to FIG. 4, doping is performed on the surface of the substrate 110 to form two junction regions within the substrate 110, including a P-type junction region 120 and an N-type junction region 130. For example, the P-type junction region 120 may be a P-type gallium arsenide (GaAs) layer, heavily doped with zinc (Zn) or magnesium (Mg) as a P-type dopant at a concentration of 10¹⁸ to 10²⁰/cm³. The N-type junction region 130 may be an N-type gallium arsenide (GaAs) layer, heavily doped with sulfur(S) or silicon (Si) at a concentration of 10¹⁸ to 10²⁰/cm³, though not limited thereto. In this embodiment, the maximum depth (D) of the two junction regions within the substrate 110 is between 5-10 micrometers (μm), though not limited thereto.

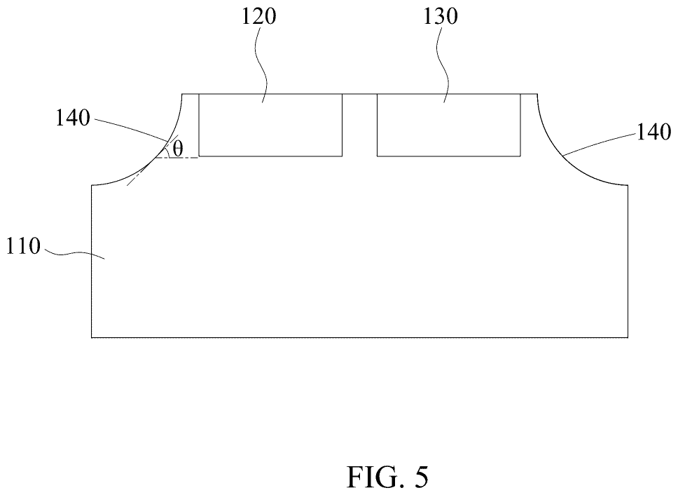

Referring to FIG. 5, a portion of the substrate 110 is removed at opposite edges to form two arc recesses 140, for example, by isotropic etching. In this embodiment, the depth (H) of the two arc recesses 140 from the top surface of the substrate 110 is greater than 10 micrometers (μm). It should be noted that the depth (H) of the arc recesses 140 is preferably greater than the maximum depth (D) of the two junction regions within the substrate to ensure the proper functioning of the arc recesses and prevent component short-circuit failure. Specifically, each arc recess 140 has an arc angle (θ) between 30° and 60°, defined as the angle between a diffusion depth line of each junction region extending to a tangent line of each arc recess 140. This arc angle (θ) should neither be too large nor too small; if too large, it becomes difficult to deposit an insulating layer on the sidewall surface of the arc recess 140 in subsequent steps; if too small, the functionality of the arc recess diminishes, failing to prevent short circuits caused by solder overflow contacting the substrate sidewall during the subsequent bonding process.

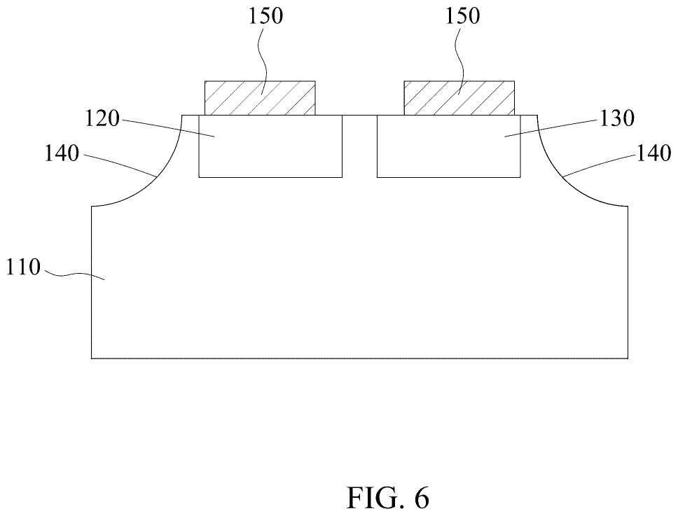

As shown in FIG. 6, an electrode plating process is performed next to form two metal electrodes 150 on the surfaces of the two junction regions of the substrate 110, with the outer side of each metal electrode 150 adjacent to each arc recess 140. Additionally, the two metal electrodes 150 are disposed on the same side of the substrate 110 as pins of a chip for the subsequent flip-chip process, spaced apart by a distance of 100-150 micrometers (μm), preferably 140-145 micrometers (μm), and each electrically connected to the P-type junction region 120 and N-type junction region 130, respectively. Specifically, in this embodiment, the material of the metal electrodes 150 may be a gold-tin alloy, a nickel-gold alloy, or other metal alloys to balance conductivity, bonding strength, thermal stability, and achieve good ohmic contact with the junction regions.

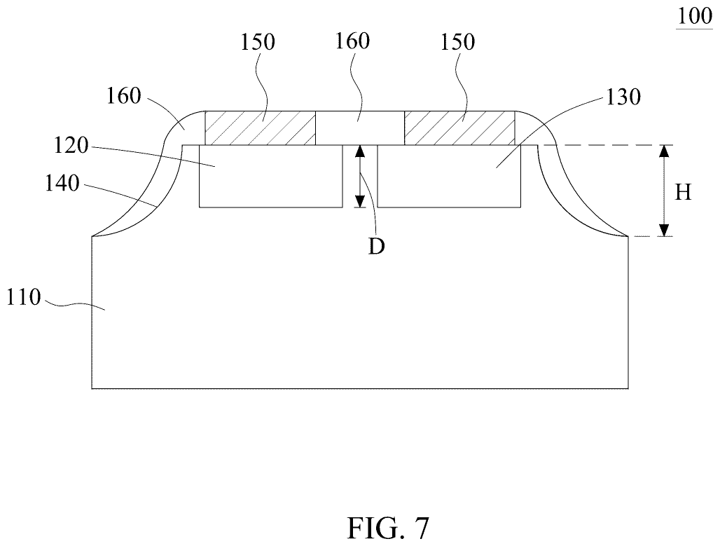

Referring to FIG. 7, a dielectric layer 160 is then formed by spin coating or deposition to cover the two arc recesses 140 at the opposite edges of the substrate and the top surface of the substrate 110 between the two metal electrodes 150 for thereby forming the flip-chip diode structure 100 of the present invention. Specifically, the dielectric layer 160 is an insulating layer with a thickness of 1-2 micrometers (μm), such as a silicon dioxide layer or a silicon nitride layer, though not limited thereto. The dielectric layer 160 covering the surface of the arc recesses 140 serves as electrical isolation to ensure that, in case of solder overflow during subsequent bonding, the overflow does not contact the N-type substrate and cause a short circuit. Preferably, after forming the dielectric layer 160, a planarization process is included to make the portion of the dielectric layer 160 between the two metal electrodes 150 substantially the same height as the two metal electrodes 150 for forming a flat surface. If the space between the two metal electrodes 150 is not filled with the dielectric layer, excess solder may fill this space during the subsequent bonding process. Over prolonged use, the excess solder between the electrodes may gradually diffuse into the junction regions and cause component failure and affect its reliability.

It should be noted that the foregoing description uses a Zener diode as an example to illustrate the flip-chip diode structure 100 and its manufacturing method of the present invention. In practice, the flip-chip diode structure 100 of the present invention can be adapted based on component requirements. For example, in another embodiment, the two junction regions may be changed to two P-type junction regions for transforming the flip-chip diode structure 100 into a flip-chip PNP-type bidirectional structure. Alternatively, the two junction regions may be changed to two N-type junction regions, and the substrate changed to a P-type substrate for transforming the flip-chip diode structure 100 into a flip-chip NPN-type bidirectional structure. These structural variations can be readily conceived with reference to the foregoing embodiments and are not elaborated here.

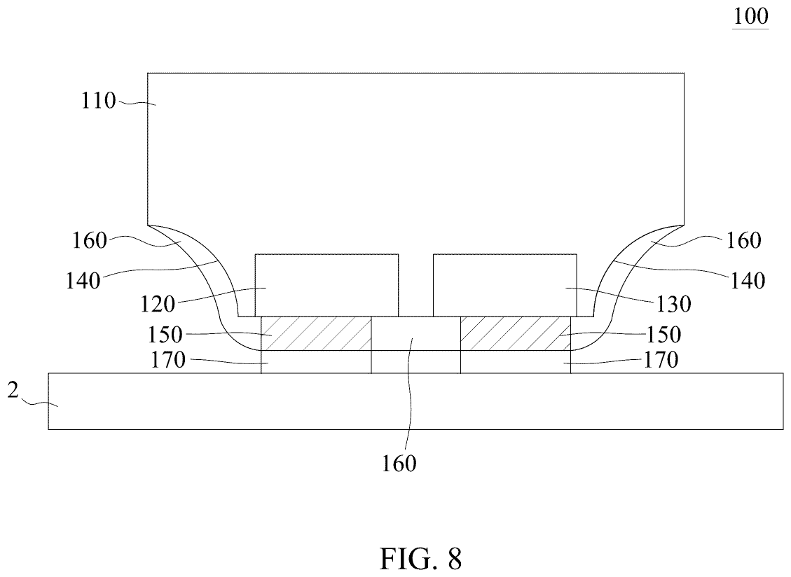

Referring to FIG. 8, a schematic diagram specifically shows the flip-chip diode structure 100 of the present invention bonded to a substrate 2 via solder 170. FIG. 8 clearly illustrates the structural feature of the present invention, wherein arc recesses 140 are provided outside the two metal electrodes 150 and solder 170. In the event of solder overflow during the bonding process, these arc recesses not only block the overflowing solder paste but also guide it to discharge toward both sides for preventing the overflow from contacting the conductive substrate and causing a short circuit and component failure.

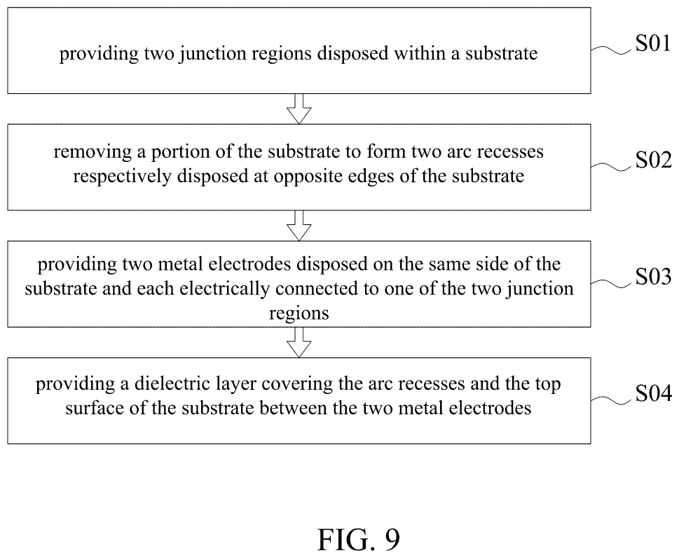

Referring to FIG. 9, a schematic diagram of the process steps for manufacturing the flip-chip diode structure of the present invention is shown. First, in step S01, two junction regions are provided within a substrate. Second, in step S02, a portion of the substrate is removed to form two arc recesses respectively disposed at opposite edges of the substrate. Next, in step S03, two metal electrodes are provided on the same side of the substrate. Finally, in step S04, a dielectric layer is provided to cover the arc recesses and the top surface of the substrate between the two metal electrodes. Detailed descriptions of the components can be referred to the foregoing content and are not repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A flip-chip diode structure, comprising:
a substrate, including two arc recesses, respectively disposed at opposite edges of the substrate;
two junction regions, disposed within the substrate;
two metal electrodes, disposed on the same side of the substrate and each electrically connected to one of the two junction regions; and
a dielectric layer, covering the arc recesses and the top surface of the substrate between the two metal electrodes,
wherein each of the arc recesses is adjacent to the outer side of one of the metal electrodes, and a maximum depth of the two junction regions within the substrate is less than a depth of the arc recesses.

2. The flip-chip diode structure of claim 1, wherein a maximum depth of the two junction regions within the substrate is between 5-10 micrometers.

3. The flip-chip diode structure of claim 1, wherein a depth of the two arc recesses is greater than 10 micrometers.

4. The flip-chip diode structure of claim 1, wherein each of the two arc recesses has an arc angle between 30°˜60°, and the arc angle is the angle between a diffusion depth line of each of the two junction regions extending to a tangent line of each of the two arc recesses.

5. The flip-chip diode structure of claim 1, wherein the dielectric layer is one of a silicon dioxide layer and a silicon nitride layer.

6. The flip-chip diode structure of claim 1, wherein a thickness of the dielectric layer is between 1-2 micrometers.

7. The flip-chip diode structure of claim 1, wherein the dielectric layer between the two metal electrodes is substantially the same height as the two metal electrodes.

8. The flip-chip diode structure of claim 1, wherein each of the metal electrodes is one of a gold-tin alloy and a nickel-gold alloy.

9. The flip-chip diode structure of claim 1, wherein the two junction regions has a P-type junction region and an N-type junction region.

10. The flip-chip diode structure of claim 1, wherein the two junction regions has two P-type junction regions.

11. The flip-chip diode structure of claim 1, wherein the two junction regions has two N-type junction regions.

12. A manufacturing method of a flip-chip diode structure, comprising:
providing two junction regions, disposed within a substrate;
removing a portion of the substrate to form two arc recesses, respectively disposed at opposite edges of the substrate;
providing two metal electrodes, disposed on the same side of the substrate and each of the two metal electrodes electrically connected to one of the two junction regions; and
providing a dielectric layer, covering the arc recesses and the top surface of the substrate between the two metal electrodes,
wherein each of the arc recesses is adjacent to the outer side of one of the metal electrodes, and a maximum depth of the two junction regions within the substrate is less than a depth of the arc recesses.

13. The manufacturing method of a flip-chip diode structure of claim 12, wherein the step of removing a portion of the substrate to form two arc recesses is to etch the portion of the substrate.

14. The manufacturing method of a flip-chip diode structure of claim 12, wherein the step of providing a dielectric layer is to coat or deposit to form the dielectric layer.

15. The manufacturing method of a flip-chip diode structure of claim 12, further comprising a step of planarizing the dielectric layer between the two metal electrodes to substantially the same height as the two metal electrodes.
